(19) United States
(12) Patent Application Publication
(10) Pub. No.: US 2024/0266220 A1
(43) Pub. Date: Aug. 8, 2024

(54) INTEGRATED LASER AND PLASMA ETCH DICING

(71) Applicant: Applied Materials, Inc., Santa Clara, CA (US)

(72) Inventors: Jonathan Bryant MELLEN, Portland, OR (US); Clinton GOH, Singapore (SG); Cheng SUN, Singapore (SG)

(21) Appl. No.: 18/105,390

(22) Filed: Feb. 3, 2023

(51) Int. Cl. H01L 21/78; B23K 26/38; B23K 26/40; H01J 37/32; H01L 21/268; H01L 21/3065; H01L 21/67; H01L 23/544

(52) U.S. Cl. CPC H01L 21/78; B23K 26/38; B23K 26/40; H01J 37/32743; H01J 37/32899; H01L 21/268; H01L 21/3065; H01L 21/67167; H01L 21/67207; H01L 23/544; H01J 2237/022; H01J 2237/334; H01L 2223/5446

(57) ABSTRACT

A method for dicing a die from a substrate for bonding that leverages laser and multiple etch processes. The method may include performing a laser cutting process to form a cut that removes a first portion of a dicing street in the substrate, performing a first plasma etch process to increase the laser kerf width to a first plasma etch width that is less than a dicing street width and to remove any non-silicon material from a bottom of the cut, and performing a second plasma etch process to increase the first plasma etch width to the dicing street width and to remove any remaining portion of the dicing street to completely separate the die from the substrate.

### FIELD

Embodiments of the present principles generally relate to semiconductor processing of semiconductor substrates.

### BACKGROUND

During bonding processes, dies are diced or separated from a substrate. The individual die then undergo a pick and place process that exerts compression forces and tension forces on the die as the die is picked up by a bonding head and placed on a substrate for bonding. The forces exerted on the die can cause the die to fracture if the die has a low die break strength, leading to reduced yields. The inventors have observed that the dicing process can have a direct impact on the die break strength.

Accordingly, the inventors have provided methods for dicing to improve die break strength performance, allowing for increased bonding yields.

### SUMMARY

Methods for dicing substrates that increase die break strength are provided herein.

In some embodiments, a method for dicing a die from a substrate may comprise performing a laser cutting process with a laser beam to form a cut that removes a first portion of a dicing street in the substrate without encroaching on silicon material layers and where a laser kerf width of the cut is less than a dicing street width of the dicing street, performing a first plasma etch process to increase the laser kerf width to a first plasma etch width that is less than the dicing street width and to remove any non-silicon dielectric material from a bottom of the cut and where the first plasma etch process is configured to remove a mix of dielectric materials and metal materials from the dicing street, and performing a second plasma etch process to increase the first plasma etch width to the dicing street width and to remove any remaining portion of the dicing street to completely separate the die from the substrate and where the second plasma etch process is configured to remove silicon material and smooth a sidewall of the die.

In some embodiments, the method further includes a substrate that includes a mask layer, an interlayer dielectric (ILD) layer, a silicon layer, and a passivation layer, a laser cutting process that removes a portion of the mask layer and the ILD layer in the dicing street, a second plasma etch process that removes a portion of the silicon layer and the passivation layer in the dicing street, a first plasma etch process and a second plasma etch process that are performed in an integrated tool without a vacuum break, a laser cutting process, a first plasma etch process, and a second plasma etch process that are performed in an integrated tool, a first plasma etch process that removes thermal damage caused by the laser cutting process, a first plasma etch process reduces particles generated by the laser cutting process, and/or a second plasma etch process that increases die break strength of the die by reducing die sidewall cracking.

In some embodiments, an integrated tool for dicing a die from a component substrate may comprise a laser chamber configured to cut non-silicon materials, at least one first plasma etching chamber configured to etch non-silicon materials, at least one second plasma etching chamber configured to etch silicon materials, and a controller configured to perform a method that includes performing a laser cutting process with a laser beam of the laser chamber to form a cut that removes a first portion of a dicing street in the component substrate without encroaching on silicon material layers and where a laser kerf width of the cut is less than a dicing street width of the dicing street, moving the component substrate in vacuum to one of the at least one first plasma etching chamber, performing a first plasma etch process to increase the laser kerf width to a first plasma etch width that is less than the dicing street width and to remove any non-silicon dielectric material from a bottom of the cut and where the first plasma etch process is configured to remove a mix of dielectric materials and metal materials from the dicing street, moving the component substrate in vacuum to one of the at least one second plasma etching chamber, and performing a second plasma etch process to increase the first plasma etch width to the dicing street width and to remove any remaining portion of the dicing street to completely separate the die from the substrate and where the second plasma etch process is configured to remove silicon material and smooth a sidewall of the die.

In some embodiments, the integrated tool may further include a mainframe configured to transport substrates between chambers in a vacuum and an equipment front end module configured to allow insertion and removal of substrates from the mainframe, a first plasma etch process that removes thermal damage caused by the laser cutting process, a first plasma etch process that reduces particles generated by the laser cutting process, and/or a second plasma etch process that increases die break strength of the die by reducing die sidewall cracking.

In some embodiments, a non-transitory, computer readable medium having instructions stored thereon that, when executed, cause a method for dicing a die from a substrate to be performed, the method may comprise performing a laser cutting process with a laser beam to form a cut that removes a first portion of a dicing street in the substrate without encroaching on silicon material layers of the substrate and where a laser kerf width of the cut is less than a dicing street width of the dicing street, performing a first plasma etch process to increase the laser kerf width to a first plasma etch width that is less than the dicing street width and to remove any non-silicon dielectric material from a bottom of the cut and where the first plasma etch process is configured to remove a mix of dielectric materials and metal materials from the dicing street, and performing a second plasma etch process to increase the first plasma etch width to the dicing street width and to remove any remaining portion of the dicing street to completely separate the die from the substrate and where the second plasma etch process is configured to remove silicon material and smooth a sidewall of the die.

In some embodiments, the method of the non-transitory, computer readable medium may further include performing on a substrate that includes a mask layer, an interlayer dielectric (ILD) layer, a silicon layer, and a passivation layer, a laser cutting process that removes a portion of the mask layer and the ILD layer in the dicing street, a second plasma etch process that removes a portion of the silicon layer and the passivation layer in the dicing street, performing a first plasma etch process and a second plasma etch process in an integrated tool without a vacuum break, performing the laser cutting process, the first plasma etch process, and the second plasma etch process in an integrated tool, performing the first plasma etch process to remove thermal damage caused by the laser cutting process, performing the first plasma etch process to reduce particles generated by the laser cutting process, and/or performing the second plasma etch process to increase die break strength of the die by reducing die sidewall cracking.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a top-down view of a component substrate in accordance with some embodiments of the present principles.

FIG. 2 depicts a cross-sectional view of a component substrate in accordance with some embodiments of the present principles.

FIG. 3 depicts an isometric view of bonding of a die to a bonding substrate in accordance with some embodiments of the present principles.

FIG. 4 is a method of dicing a die from a component substrate in accordance with some embodiments of the present principles.

FIG. 5 depicts cross-sectional views of a dicing street in a component substrate in accordance with some embodiments of the present principles.

FIG. 6 depicts a schematic top-down view of an integrated processing tool for dicing substrates in accordance with some embodiments of the present principles.

FIG. 7 is a method of bonding in accordance with some embodiments of the present principles.

FIG. 8 depicts a cross-sectional view of a bonding substrate after an interdie gapfill in accordance with some embodiments of the present principles.

FIG. 9 depicts cross-sectional views of a surface of a sidewall in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide an enhanced process for dicing (separating) of dies from a component substrate. The integration of a laser, a back-end-of-the-line (BEOL) plasma etch, and a silicon plasma etch produces a superior process for separation of the dies with lower defects. The process advantageously increases the die break strength of the die by reducing particle contamination and smoothing sidewalls of the die during the dicing process. The enhanced quality of the dicing process increases die yield during bonding by preventing cracking of the die during handling and also after interdie gapfilling procedures by reducing delamination caused by particle contamination and cracks in the die sidewalls.

Current plasma dicing strategies cause contamination and rough die sidewalls due to the use of lasers which can melt and reform removal material onto the sidewalls of the die. The methods of the present principles use a laser to only remove thicker top metal and/or dielectric material BEOL layers of an interlayer dielectric (ILD) layer. A first stage plasma etch is then used to remove thinner metal BEOL and/or mixed dielectric material of the ILD layer. The first stage plasma etch process will remove any damaged sidewall and laser induced debris from the laser process, leaving behind a smoother sidewall which is debris-free. A second stage plasma etch is then performed to remove thicker silicon layers to increase the etching rate and also to further smooth the die sidewalls. A smooth, debris-free sidewall is needed to achieve high die break strength and higher yields for interdie gapfill after bonding.

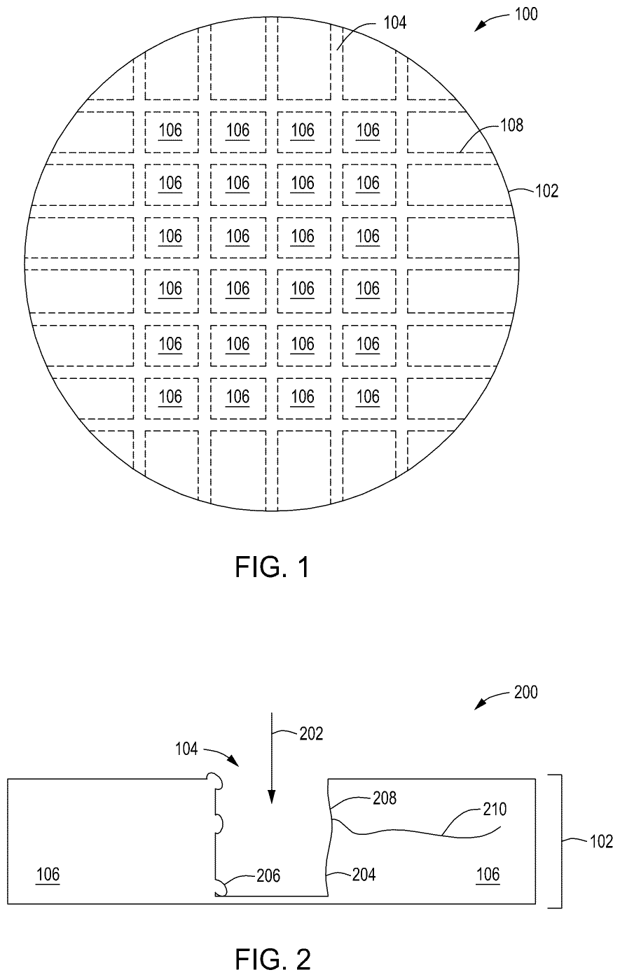

FIG. 1 is a top-down view 100 of a component substrate 102 with a dicing street 104 of a plurality of dicing streets marked by dashed lines 108 on the component substrate 102. A component substrate as used herein is a substrate on which die have been formed and is diced to extract the individual die, so the die can be placed on another substrate or bonding substrate which may have a plurality of dies bonded to the surface. The dicing street 104 may be an area of the component substrate 102 in which test pads or other redistribution layers (RDL) (metal and/or dielectric layers) may be formed on top of a bulk silicon layer of the component substrate 102. Material in the area covered by the dicing street 104 is meant to be completely removed during dicing processes so that, for example, only the area of the die 106 remains.

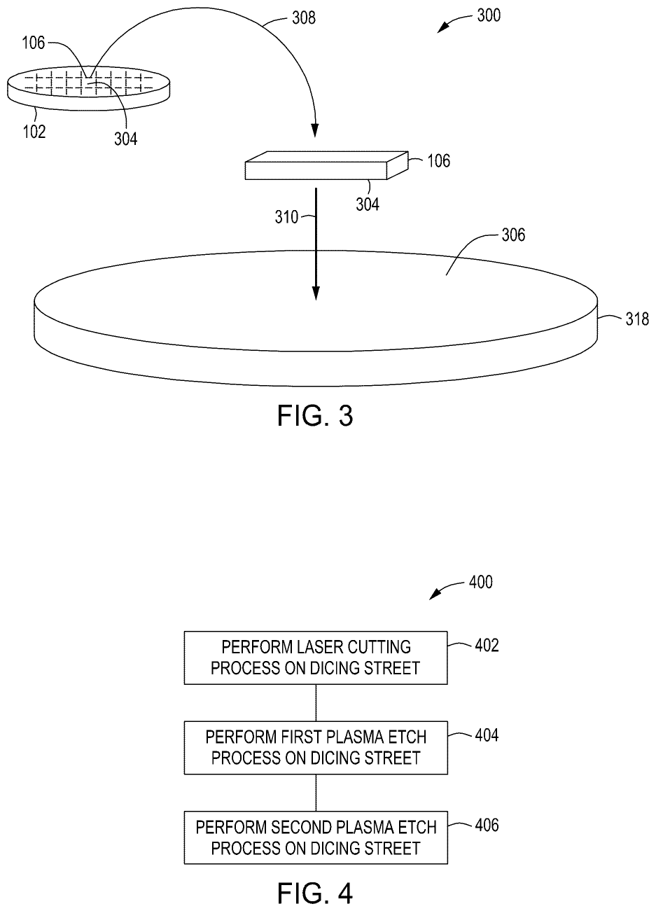

In traditional processes that use a laser beam 202 to remove the bulk of the dicing street 104, defects that impact bonding and interdie gapfilling are formed as depicted in a cross-sectional view 200 of the component substrate 102 of FIG. 2. The laser beam 202, during ablation, heats up the material in the dicing street 104 and recasts 206 the material into the sidewalls and/or onto a mask on top of the component substrate, creating mask defects and/or sidewall contaminations that promote interdie gapfill delamination. In addition, the laser beam 202 creates roughened sidewalls 204 that weaken the die sidewalls 208 and can cause fractures or cracks 210 to form during handling of the die by a bonder, dramatically reducing the die break strength and significantly lowering yields. FIG. 3 is an isometric view 300 depicting a bonding process 310 of the die 106 from the component substrate 102 to a bonding substrate 318. The component substrate 102 is diced and the die 106 undergoes compression as the die 106 is picked up and then undergoes expansion as the die 106 is removed from a tape backing from the component substrate 102. The die 106 is then flipped 308 (die upper surface 304 becomes the die bonding surface) and placed on the bonding substrate 318 while undergoing compression again to bond the die 106 to the surface 306 of the bonding substrate 318. Both the compressive and tensile forces applied to the die 106 during the bonding process can easily crack and destroy the die 106 if the die exhibits low die break strength due to sidewall defects caused by the dicing process.

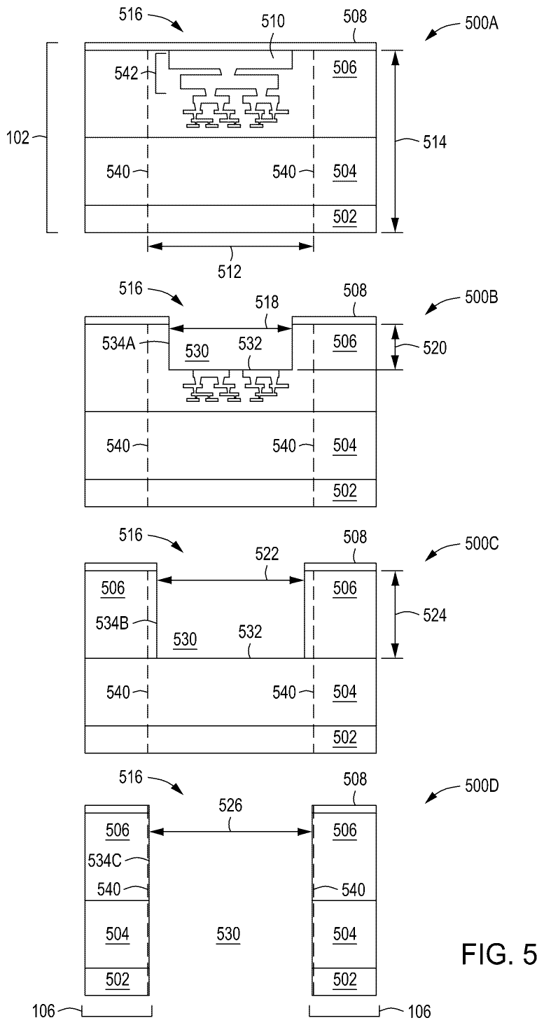

FIG. 4 is a method 400 of dicing a component substrate with significantly reduced die sidewall defects. FIG. 5 will be referenced during the description of the method 400. In a cross-sectional view 500A of FIG. 5, a portion of the component substrate 102 is depicted. The component substrate 102, for example, may have a passivation layer 502, a silicon layer 504, an ILD layer 506, and a mask 508. A dicing street 516 is defined by dashed sidewalls 540 which will also form the sidewalls of the die 106 after dicing. The dicing street 516 has a dicing street width 512. In general, a die total thickness 514 incorporates the layers of the component substrate 102 such as, for example, the passivation layer 502, the silicon layer 504, and the ILD layer 506. Although the mask 508 is present and removed during dicing in the dicing street 516, the mask 508 thickness is negligible and may or may not be present before or after a dicing process and is not included in the die total thickness 514. The ILD layer 506 is a mixed dielectric material layer without or with metal structures 510 including interconnects and test pads embedded into the ILD layer 506. The upper metal structures 542 are typically thicker (e.g., 800 nm to 1000 nm and above, etc.) and cannot be easily removed by plasma etching processes in a timely manner.

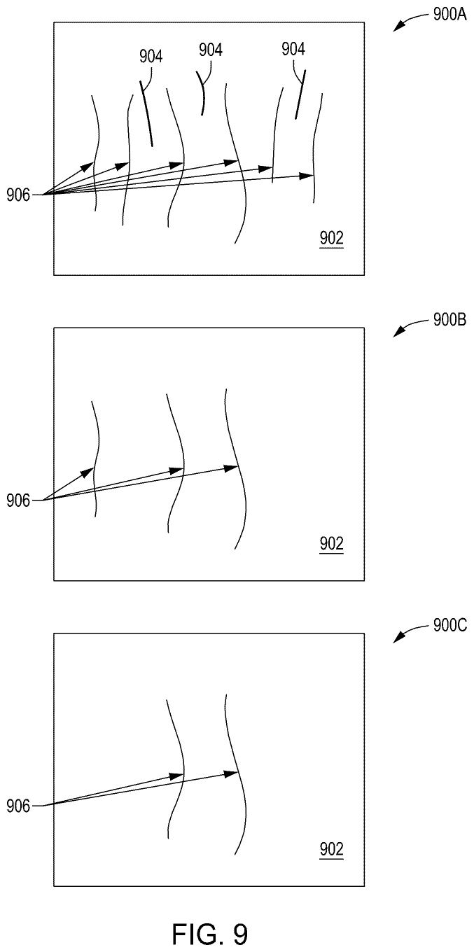

In block 402 of the method 400, a laser cutting process is performed on the dicing street 516 as depicted in view 500B of FIG. 5. In some embodiments, the laser is used to form a cut 530 that removes a first portion 520 of the dicing street 516 that contains the bulk of the upper metal structures 542 with the greatest thicknesses. In some embodiments, the laser is used to form a cut 530 that removes a first portion 520 of the dicing street 516 that contains the bulk of the mixed dielectric materials of the ILD layer. The laser will also remove a portion of the mask 508 if present. In some embodiments, the laser cutting process removes at least 20% of the die total thickness 514 without encroaching on the material of the silicon layer 504. The laser cutting process produces a laser kerf width 518 that is less than the dicing street width 512 to allow subsequent etching processes to remove the damage caused by the laser cutting process. The laser cutting process will produce recast material (debris/contamination) and roughened surfaces on sidewalls 534A and a bottom 532 of the cut 530. FIG. 9 depicts a surface 902 of a sidewall of a dicing street after a laser cut. For example, the laser leaves the surface 902 with cracks 904 and striations 906 as depicted in a view 900A.

Recasting of material is a major concern when laser cutting silicon material. In addition, another concern is that plasma etching of mixed materials (e.g., metals and/or dielectrics) is difficult. By using the laser cutting process to remove the bulk of the mixed materials (e.g., mix of metals and dielectrics or mix of dielectric materials) while stopping short of lasing into silicon material (silicon layer 504), the speed of the dicing process is improved without creating silicon recast material in the laser kerf or on the mask. In other words, the laser cutting process can be used to quickly remove metals that plasma etching can not easily perform, or the laser cutting process can be used for clearing the bulk of the ILD layer 506 so that the subsequent plasma etch process is of a shorter duration to increase speed of the integrated dicing process (laser removal is much faster than plasma etching). Despite the advantages of faster material removal, the laser cutting process can also produce more recast material on the mask 508 which is difficult to remove. Thus, a balance between the fast removal rate and increased mask defects may be taken into consideration to determine the extent (e.g., laser kerf width and/or laser cutting depth, etc.) of the laser cutting process for the integrated dicing process.

In block 404, a first plasma etch process is performed on the dicing street 516 as depicted in view 500C of FIG. 5. The first plasma etch process increases the laser kerf width 518 to a first plasma etch width 522 that is less than the dicing street width 512 to form smooth sidewalls 534B. The first plasma etch process is configured to remove a second portion consisting of a mix of dielectric materials and/or metal materials from the dicing street 516 and is used in BEOL processes. After removal of the second portion, a depth 524 of the cut 530 is increased to approximately the silicon layer 504. The first plasma etch process removes any non-silicon dielectric material from the bottom 532 of the cut 530 including any remaining portions of the metal structures 510 and dielectric materials. The first plasma etch process removes thermal damage caused by the laser cutting process such as contamination (particles) caused by recasting of the ablated materials and rough surface caused during ablation. The first plasma etch process aids in increasing die break strength by alleviating the negative effects of the laser cutting process that facilitate cracks and other defects in the die sidewalls. For example, the first plasma etch process removes the cracks 904 and reduces the striations 906 of the surface 902 as depicted in a view 900B of FIG. 9.

The primary removal of material occurs at the bottom 532 of the cut 530 as the first plasma etch process is an anisotropic etch process. With the bulk of the metal material and/or dielectric material removed by the previous laser cutting process, the first plasma etch process can efficiently etch through the thinner remaining metals and/or dielectric materials down to at least an underlying layer of bulk silicon (silicon layer 504). The first plasma etch process may etch into the underlying silicon layer 504. However, since the subsequent plasma etch process is more proficient at removing silicon material, speed of the integrated dicing process is increased if the first plasma etch process does not encroach substantially into the silicon layer 504. The depth and width of the first plasma etch process can be controlled with process tuning.

In block 406 of the method 400, a second plasma etch process is performed on the dicing street 516 as depicted in view 500D of FIG. 5. The second plasma etch process increases the first plasma etch width 522 to a second plasma etch width 526 which is approximately equal to the dicing street width 512. The second plasma etch process removes any remaining portion of the dicing street 516 to completely separate the die from the substrate. The second plasma etch process is configured to remove silicon material and to further smooth the sidewalls 534C which also form the sidewalls of the die 106, substantially increasing the die break strength of the die 106. In some embodiments, the second plasma etch process may remove the remaining portion of the silicon layer 504 and the passivation layer 502 in the dicing street 516. During the first plasma etch process, the etching may remove a small portion of the silicon layer 504 along with the any remaining metal structures and/or dielectric materials. The bulk of the silicon layer 504, however, is removed by the second plasma etch process to increase the removal rate, as the second plasma etch process is configured for silicon removal. Similarly, the second plasma etch process will also remove portions of the remaining sidewall dielectric material on the ILD layer 506 to increase the width of the cut 530 to the die street sidewalls (dashed sidewalls 540). The primary removal of material will occur at the bottom 532 of the cut 530, as the second plasma etch process is an anisotropic etch process. The second plasma etch process increases the die break strength of the die 106 by continuing to remove contaminants and maintain the smooth the sidewalls to reduce die sidewall cracking. For example, the second plasma etch process further reduces the striations 906 of the surface 902 as depicted in a view 900C of FIG. 9.

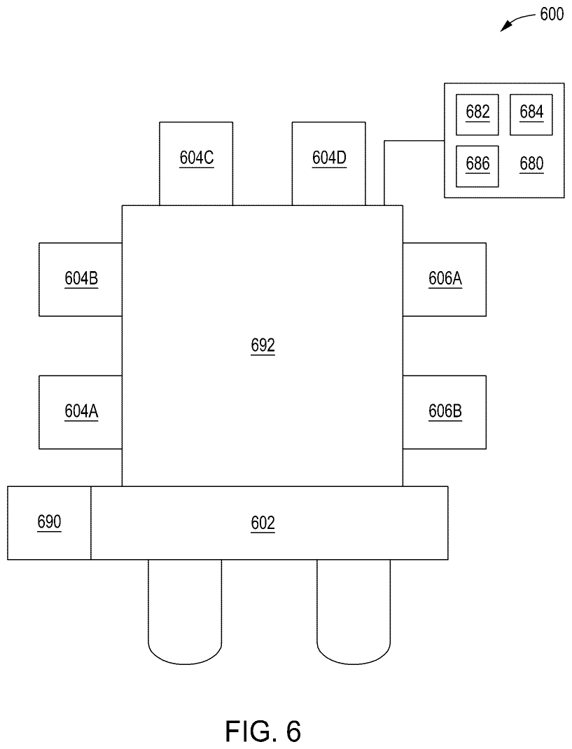

The method 400 may be performed with a standalone laser chamber. The first plasma etch process and the second plasma etch process may be performed in individual chambers that are linked via a vacuum transport system such as in an integrated tool (e.g., see FIG. 6 and description below). In some embodiments, the laser chamber may also be part of an integrated processing tool 600 for dicing substrates that contains one or more first plasma etch chamber (604A-604D) and one or more second plasma etch chamber (606A, 606B) connected via a mainframe 680 as depicted in a schematic top-down view of FIG. 6. The integrated processing tool 600 generally includes an equipment front end module (EFEM) 602 for accepting and delivering substrates while the mainframe 692 transports substrates to the appropriate chamber in a vacuum environment. In some embodiments, a laser module 690 or chamber may also be attached to the EFEM 602 to allow for laser dicing operations to be performed on substrates prior to or after entry into the EFEM 602. The integrated processing tool 600 allows the laser to quickly cut through the top portions of the dicing streets and pass the substrate on to the first plasma etch chamber and the then the second plasma etch chamber without exposure to atmosphere and eliminating queue time concerns between laser and etching processes. The overall footprint of the laser and etching chambers is also reduced in the integrated processing tool 600.

A controller 680 may also be used to control the integrated processing tool 600. The controller 680 may use a direct control of the integrated processing tool 600, or alternatively, by controlling the computers (or controllers) associated with the integrated processing tool 600. In operation, the controller 680 enables data collection and feedback from the integrated processing tool 600 to optimize performance of the integrated processing tool 600 and to control the processing flow according to methods described herein. The controller 680 generally includes a central processing unit (CPU) 682, a memory 684, and a support circuit 686. The CPU 682 may be any form of a general-purpose computer processor that can be used in an industrial setting. The support circuit 686 is conventionally coupled to the CPU 682 and may comprise a cache, clock circuits, input/output subsystems, power supplies, and the like. Software routines, such as methods as described above may be stored in the memory 684 and, when executed by the CPU 682, transform the CPU 682 into a specific purpose computer (controller 680). The software routines may also be stored and/or executed by a second controller (not shown) that is located remotely from the integrated processing tool 600.

The memory 684 is in the form of computer-readable storage media that contains instructions, when executed by the CPU 682, to facilitate the operation of the semiconductor processes and equipment. The instructions in the memory 684 are in the form of a program product such as a program that implements methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

The primary purpose of linking the two plasma etch chambers via a vacuum transport is to maintain the cleanliness of the component substrate between etch processes. In some embodiments, the removal amounts and/or rates of the method 400 may be adjusted between the three integrated processes based on a desired throughput versus die sidewall quality. For example, in non-hybrid bonding processes, a slightly lower quality sidewall may be traded for higher throughput (e.g., increased laser bulk material removal, etc.). While for hybrid bonding processes, a higher quality sidewall may be more beneficial than a slightly slower throughput rate (e.g., decreased laser bulk material removal to reduce thermal damage and/or contaminants, etc.).

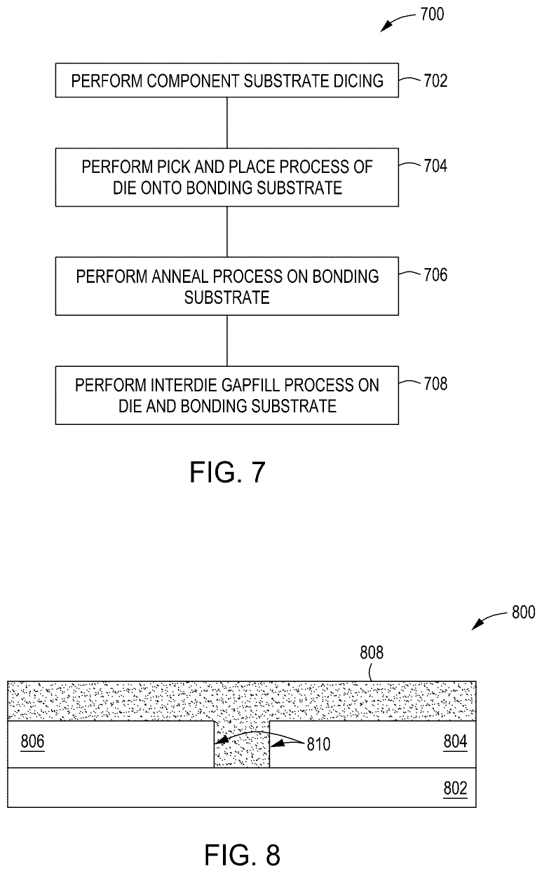

FIG. 7 is a method 700 for processing a die from a component substrate in a hybrid bonding process. A hybrid bonding process involves bonding of both dielectric materials, which are usually bonded upon contact, and metallic materials, which usually require a subsequent annealing process to complete the connections. The method 400 can also be performed to dice component substrates that are used in other processes besides hybrid bonding. The benefits and advantages of the method 400 are, however, especially useful in hybrid bonding processes. In block 702 of the method 700, the component substrate undergoes a dicing process as found in method 400 to ensure high die break strength and low defects (e.g., contamination, cracking, rough sidewalls, etc.). In block 704, a pick and place process is performed to bond the die onto a bonding substrate similarly to the process depicted in FIG. 3 and described above. The dielectric materials of the die will bond to the bonding substrate upon contact, and the bonding process may also comprise further applied pressure to ensure a void free bond between the die and bonding substrate. Any die with low die break strength will typically fail during the bonding process, reducing the yield. By using the method 400, the die will have increased die break strength and the bonding yield will also be increased.

In block 706, an anneal process is performed on the bonding substrate to allow metallic portions of the die and bonding substrate to join together. The anneal process may or may not be required in some bonding sequences. In block 608, an interdie gapfill process is performed on the bonding substrate as depicted in a view 800 of FIG. 8. In FIG. 8, a first die 804 and a second die 806 have been bonded to a bonding substrate 802. In block 708, an interdie gapfill process is then been performed, for example, by a chemical vapor deposition (CVD) process to produce an interdie gapfill layer 808. Because the first die 804 and the second die 806 were diced using the method 400, the sidewalls 810 of the first die 804 and the second die 806 have no or little defects such as rough surfaces and contamination (particles). The reduction of defects substantially reduces delamination that may occur between the interdie gapfill layer 808 and the sidewalls 810 of the first die 804 and the second die 806, increasing yields.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for dicing a die from a substrate, comprising:
performing a laser cutting process with a laser beam to form a cut that removes a first portion of a dicing street in the substrate without encroaching on silicon material layers and wherein a laser kerf width of the cut is less than a dicing street width of the dicing street;
performing a first plasma etch process to increase the laser kerf width to a first plasma etch width that is less than the dicing street width and to remove any non-silicon dielectric material from a bottom of the cut, wherein the first plasma etch process is configured to remove a mix of dielectric materials and metal materials from the dicing street; and
performing a second plasma etch process to increase the first plasma etch width to the dicing street width and to remove any remaining portion of the dicing street to completely separate the die from the substrate, wherein the second plasma etch process is configured to remove silicon material and smooth a sidewall of the die.

2. The method of claim 1, wherein the substrate includes a mask layer, an interlayer dielectric (ILD) layer, a silicon layer, and a passivation layer.

3. The method of claim 2, wherein the laser cutting process removes a portion of the mask layer and the ILD layer in the dicing street.

4. The method of claim 2, wherein the second plasma etch process removes a portion of the silicon layer and the passivation layer in the dicing street.

5. The method of claim 1, wherein the first plasma etch process and the second plasma etch process are performed in an integrated tool without a vacuum break.

6. The method of claim 1, wherein the laser cutting process, the first plasma etch process, and the second plasma etch process are performed in an integrated tool.

7. The method of claim 1, wherein the first plasma etch process removes thermal damage caused by the laser cutting process.

8. The method of claim 1, wherein the first plasma etch process reduces particles generated by the laser cutting process.

9. The method of claim 1, wherein the second plasma etch process increases die break strength of the die by reducing die sidewall cracking.

10. An integrated tool for dicing a die from a component substrate, comprising:
a laser chamber configured to cut non-silicon materials;
at least one first plasma etching chamber configured to etch non-silicon materials;
at least one second plasma etching chamber configured to etch silicon materials; and
a controller configured to perform a method including:
performing a laser cutting process with a laser beam of the laser chamber to form a cut that removes a first portion of a dicing street in the component substrate without encroaching on silicon material layers and wherein a laser kerf width of the cut is less than a dicing street width of the dicing street;
moving the component substrate in vacuum to one of the at least one first plasma etching chamber;
performing a first plasma etch process to increase the laser kerf width to a first plasma etch width that is less than the dicing street width and to remove any non-silicon dielectric material from a bottom of the cut, wherein the first plasma etch process is configured to remove a mix of dielectric materials and metal materials from the dicing street;
moving the component substrate in vacuum to one of the at least one second plasma etching chamber; and
performing a second plasma etch process to increase the first plasma etch width to the dicing street width and to remove any remaining portion of the dicing street to completely separate the die from the component substrate, wherein the second plasma etch process is configured to remove silicon material and smooth a sidewall of the die.

11. The method of claim 10, wherein the integrated tool further comprises:
a mainframe configured to transport substrates between chambers in a vacuum; and
an equipment front end module configured to allow insertion and removal of substrates from the mainframe.

12. The method of claim 10, wherein the first plasma etch process removes thermal damage caused by the laser cutting process.

13. The method of claim 10, wherein the first plasma etch process reduces particles generated by the laser cutting process.

14. The method of claim 10, wherein the second plasma etch process increases die break strength of the die by reducing die sidewall cracking.

15. A non-transitory, computer readable medium having instructions stored thereon that, when executed, cause a method for dicing a die from a substrate to be performed, the method comprising:
performing a laser cutting process with a laser beam to form a cut that removes a first portion of a dicing street in the substrate without encroaching on silicon material layers of the substrate and wherein a laser kerf width of the cut is less than a dicing street width of the dicing street;
performing a first plasma etch process to increase the laser kerf width to a first plasma etch width that is less than the dicing street width and to remove any non-silicon dielectric material from a bottom of the cut, wherein the first plasma etch process is configured to remove a mix of dielectric materials and metal materials from the dicing street; and
performing a second plasma etch process to increase the first plasma etch width to the dicing street width and to remove any remaining portion of the dicing street to completely separate the die from the substrate, wherein the second plasma etch process is configured to remove silicon material and smooth a sidewall of the die.

16. The non-transitory, computer readable medium of claim 15, wherein the substrate includes a mask layer, an interlayer dielectric (ILD) layer, a silicon layer, and a passivation layer.

17. The non-transitory, computer readable medium of claim 16, wherein the laser cutting process removes a portion of the mask layer and the ILD layer in the dicing street.

18. The non-transitory, computer readable medium of claim 16, wherein the second plasma etch process removes a portion of the silicon layer and the passivation layer in the dicing street.

19. The non-transitory, computer readable medium of claim 15, further comprising:
performing the first plasma etch process and the second plasma etch process in an integrated tool without a vacuum break.

20. The non-transitory, computer readable medium of claim 15, further comprising a, b, c, or d:
(a) performing the laser cutting process, the first plasma etch process, and the second plasma etch process in an integrated tool; or
(b) performing the first plasma etch process to remove thermal damage caused by the laser cutting process; or
(c) performing the first plasma etch process to reduce particles generated by the laser cutting process; or
(d) performing the second plasma etch process to increase die break strength of the die by reducing die sidewall cracking.
